(19) United States
(12) Patent Application Publication
(10) Pub. No.: US 2009/0075455 A1
(43) Pub. Date: Mar. 19, 2009

(54) Growing N-polar III-nitride Structures

(76) Inventor: Umesh Mishra, Montecito, CA (US)

Correspondence Address: FISH & RICHARDSON P.C., PO BOX 1022, MINNEAPOLIS, MN, 55440-1022, US

(21) Appl. No.: 12/209,504

(22) Filed: Sep. 12, 2008

Related U.S. Application Data
(60) Provisional application No. 60/972,467, filed on Sep. 14, 2007.

(51) Int. Cl. H01L 21/762

(52) U.S. Cl. 438/458; 257/E21.568

(57) ABSTRACT

Methods of forming a stable N-polar III-nitride structure are described. A Ga-polar device can be formed on a substrate. A carrier wafer is attached to the Ga-polar surface. The substrate is removed from the assembly. The N-polar surface that remains is offcut and, optionally, subsequent layers are formed on the offcut surface.

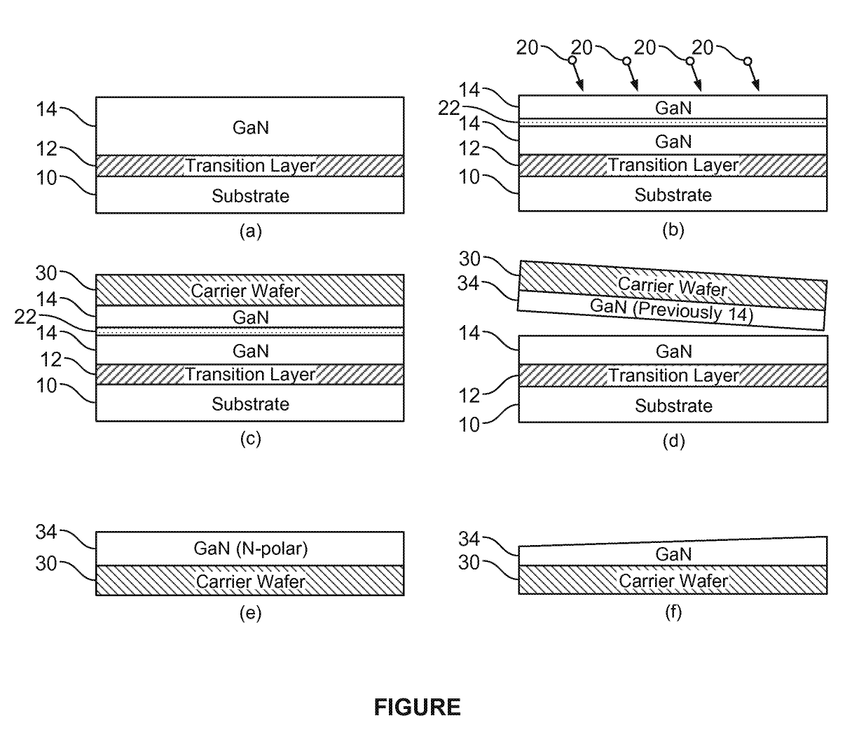

### CROSS-REFERENCE TO RELATED APPLICATIONS

This application claims priority to U.S. Provisional Application Ser. No. 60/972,467, filed on Sep. 14, 2007, which is incorporated by reference for all purposes.

### TECHNICAL FIELD

This invention relates to semiconductor materials.

### BACKGROUND

With the ongoing development of III-nitride technology, Gallium Nitride (GaN) semiconductor devices have emerged as an attractive candidate for solid-state lighting as well as in high power and high temperature applications. AlInGaN alloys with bandgaps spanning from the infrared to ultraviolet range can be epitaxially grown, allowing for visible and UV emitters and detectors. The wide bandgap and high thermal conductivity of GaN, combined with the high mobilities and large sheet charge concentrations of GaN 2-dimensional electron gases (2DEGs), make GaN an excellent choice for high power, high temperature applications.

Currently, GaN substrates tend to be small, expensive, and are not available in very large quantities. Therefore, GaN is most often grown epitaxially, such as by MOCVD, MBE, or HVPE, on foreign substrates, such as sapphire, silicon carbide (SiC), or silicon (Si). One well-developed growth process results in GaN oriented in the [0 0 0 1] direction, or in other words Ga-polar C-plane GaN. For a number of devices, it is necessary that the GaN and additional device layers be N-polar in order for the device to operate properly. The development of N-polar GaN has lagged behind that of Ga-polar GaN for at least the following reasons: when growing GaN on a foreign substrate, the material naturally nucleates in such a way that results in Ga-polar GaN and the N-face of GaN is much less thermally stable than the Ga-face, so it is difficult to subsequently grow more N-polar material on top of N-polar GaN.

### SUMMARY

Processes for achieving high quality N-polar GaN layers on which additional N-polar material (GaN or AlInGaN) can be readily grown are described. In some embodiments, standard Ga-polar GaN is grown on a foreign substrate, such as sapphire, SiC, or Si. The surface is bonded to a carrier wafer, the substrate is then removed to expose an N-polar face, and this N-polar face is polished to obtain off-angle orientations. Optimal off-cut orientations are also identified.

In one aspect, a method of forming an N-polar III-nitride structure is described. A III-nitride layer is formed on substrate, wherein the III-nitride layer has a Ga-polar face. A carrier wafer is bonded to the Ga-polar face to from an assembly. The substrate is removed from the assembly. An off-angle exposed surface of the assembly is formed to form the N-polar III-nitride structure.

The details of one or more embodiments of the invention are set forth in the accompanying drawings and the description below. Other features, objects, and advantages of the invention will be apparent from the description and drawings, and from the claims.

### DESCRIPTION OF DRAWINGS

The FIGURE includes schematic representations of the structure while being formed.

Like reference symbols in the various drawings indicate like elements.

### DETAILED DESCRIPTION

As shown in part (a) of the FIGURE, a standard Ga-polar III-N layer 14, such as a GaN layer, is first grown on a foreign substrate 10, which may be sapphire, SiC, Si, or any other substrate suitable for the growth of standard Ga-polar (III-N materials). Optionally, a transition layer 12 is included between the substrate 10 and the GaN layer 14. The transition layer 12 can be a III-N layer grown at low temperature. Referring to part (b) of the FIGURE, in one embodiment, atoms 20 are then implanted into the III-N layer 14, resulting in layer 22, as seen in part (b) of the FIGURE. The implanted atoms weaken the bonds between the group III elements and nitrogen in layer 22, allowing for GaN layer 14 to be split, such as by using so-called smart cut technology in which the entire structure is annealed or an annealing strip is applied to the surface, causing layer 14 to separate at the implant site. Hydrogen or helium atoms are commonly used for the implant species 20. The implanted atoms are implanted at an angle relative to the surface normal to prevent them from channeling deep into the structure, such as at an implant angle of about 7° or larger, for example, between about 7 and 10 degrees.

Referring to part (c) of the FIGURE, the surface of the structure is then bonded to a carrier wafer 30, such as AlN, sapphire, SiC, Si, or any other material suitable for bonding. The structure is then annealed, or an annealing strip is applied to the surface, causing III-N layer 14 to split along the implant site, as shown in part (d) of the FIGURE. The assembly of the carrier wafer 30 and the remaining portion of III-N layer 14 is turned over so that the N-face of the III-N material is exposed. The III-N layer is now an N-polar layer 34, since the N-face is now exposed, as shown in part (e) of the FIGURE. The surface of layer 34 is polished to obtain an off-angle orientation, as shown in part (f) of the FIGURE. N-polar GaN is relatively easy to polish because of the thermal instability of the N-face. In one embodiment, the surface is off-angle towards the M-plane at an angle of 10° or less, such as 9°, 8°, 7°, 6° or 5° or less. Alternatively, the surface may be off-angle towards the A-plane at an angle of 10° or less, such as 9°, 8°, 7°, 6° or 5° or less. The off-angle allows for more stable growth of additional N-polar III-N materials as compared to an N-polar surface which is not off cut. N-polar device structures may now be readily grown on the off-angle III-N layer 34.

In a variation to this process, substrate layer 10 and transition layer 12, as shown in parts (a)-(d) of the FIGURE are removed by methods other than smart-cut. For example, laser ablation may be used to remove substrate layer 10, followed by etching and/or mechanical polishing to remove transition layer 12 and a portion of III-N layer 14.

Layers can be grown on the off-angle N-polar structure that is formed and additional processing, such as doping, addition of gate electrodes, source and drain contacts and other suitable processes for forming devices can be performed on the N-polar structure.

The first III-N material, which is grown as a Ga-face layer may be grown by any suitable epitaxy method. Similarly, various suitable epitaxy techniques may be used to grow device epilayers on the resulting N-face material. For example, MOCVD, HVPE or MBE may be used. The resulting N-face III-N material template may be used for subsequent growth of various structures for various applications, including but not limited to, III-N high electron mobility transistors (HEMTs), schottky diodes, light emitting diodes (LEDs), laser diodes and solar cells.

A number of embodiments of the invention have been described. Nevertheless, it will be understood that various modifications may be made without departing from the spirit and scope of the invention. Accordingly, other embodiments are within the scope of the following claims.

What is claimed is:

1. A method of forming an N-polar III-nitride structure, comprising:
forming a III-nitride layer on substrate, wherein the III-nitride layer has a Ga-polar face;
bonding a carrier wafer to the Ga-polar face to from an assembly;
removing the substrate from the assembly; and
forming an off-angle exposed surface of the assembly to form the N-polar III-nitride structure.

2. The method of claim 1, further comprising implanting the III-nitride layer with hydrogen atoms, wherein removing the substrate from the assembly is performed along a location in which the hydrogen atoms are implanted.

3. The method of claim 2, wherein the removing comprises annealing the assembly.

4. The method of claim 2, wherein implanting comprises implanting at an angle of about 7°.

5. The method of claim 1, wherein forming an off-angle exposed surface comprises polishing.

6. The method of claim 1, wherein removing comprises one of ablation or etching.

7. The method of claim 1, wherein removing comprises removing a portion of the III-nitride layer.

8. The method of claim 1, wherein forming an off-angle exposed surface includes forming an off-angle towards the M-plane at an angle of 10° or less.

9. The method of claim 1, wherein forming an off-angle exposed surface includes forming an off-angle towards the A-plane at an angle of 10° or less.

10. The method of claim 1, wherein forming a III-nitride layer includes forming the III-nitride layer on a transition layer on the substrate.

11. The method of claim 1, further comprising epitaxially growing a GaN based device on the N-polar III-nitride structure.

12. The method of claim 10, wherein the GaN based device is a GaN HEMT.

13. The method of claim 10, wherein the GaN based device is an LED.

14. The method of claim 10, wherein the GaN based device is a laser diode.

15. The method of claim 10, wherein the GaN based device is a solar cell.
